(19) United States
(12) Patent Application Publication
(10) Pub. No.: US 2013/0037966 A1
(43) Pub. Date: Feb. 14, 2013

(54) SEMICONDUCTOR DEVICE DIE BONDING

(71) Applicants: Shunan QIU, Tianjin (CN); Guoliang Gong, Tianjin (CN); Junhua Luo, Tianjin (CN); Xuesong Xu, Tianjin (CN)

(72) Inventors: Shunan QIU, Tianjin (CN); Guoliang Gong, Tianjin (CN); Junhua Luo, Tianjin (CN); Xuesong Xu, Tianjin (CN)

(73) Assignee: FREESCALE SEMICONDUCTOR, INC, Austin, TX (US)

(21) Appl. No.: 13/495,011

(22) Filed: Jun. 13, 2012

(30) Foreign Application Priority Data
Aug. 10, 2011 (CN) 201110227755.1

(51) Int. Cl. H01L 23/48; H01L 21/78

(52) U.S. Cl. 257/782; 438/113; 257/E21.599; 257/E23.01

(57) ABSTRACT

A semiconductor device includes a semiconductor die having first and second opposing faces and an edge surface. The edge surface has an undercut under the first face. The second face of the semiconductor die is bonded to a bonding surface of a die support member, such as a thermally conductive flag of a lead frame, with a die attach material. A fillet of the bonding material is formed within the undercut.

### BACKGROUND OF THE INVENTION

The present invention is directed to a method of semiconductor die packaging and, more particularly, to a method of controlling the fillet height of a material used to attach the semiconductor die to a die support member.

Semiconductor device packaging fulfils basic functions such as providing external electrical connections to/from a semiconductor die and protecting the die against mechanical and environmental stresses. In a common method of packaging dies, a wafer is singulated and the singulated dies are bonded on a die support, such as a substrate or a die pad or flag of a lead frame. During the die bonding process, viscous bonding material placed between the die and the support solidifies. Typical bonding materials are polymer adhesives such as epoxy resin, soft solder or eutectic alloy.

During the die bonding operation, the bonding material may flow up the edge of the die, forming a fillet. The height of the fillet is a production variable that it is important to control. In order to increase packaging density, the thickness of the semiconductor dies is minimized. For example, the backside of the wafer may be ground to reduce the thickness of the wafer before singulation of the semiconductor dies. However, reducing die thickness increases the risk of excessive fillet height; that is, the state in which the die bonding material overflows the edge of the die and onto the active face of the die, which in turn can cause wire bonding defects such as short circuits of the contact pads on the die. Thus, it would be advantageous to be able to accurately control the fillet height and thus prevent die bonding material from flowing onto the active face of the die.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale.

FIG. 1 is a schematic sectional view of a conventional semiconductor device having a semiconductor die bonded to a die support element;

FIG. 2 is a schematic sectional view of a semiconductor device having a semiconductor die bonded to a die support element in accordance with one embodiment of the invention, given by way of example; and

FIGS. 3 to 7 are sectional views of the semiconductor device of FIG. 2 at various stages during an assembly or packaging process in accordance with one embodiment of the invention, given by way of example.

### DETAILED DESCRIPTION OF PREFERRED EMBODIMENTS OF THE INVENTION

Semiconductor device packages for surface mounting have exposed electrical contacts. The exposed electrical contacts are connected internally with electrical contact pads on an active face of the semiconductor die. Various techniques are available for connecting the exposed electrical contacts of the package with the embedded semiconductor die. The semiconductor devices shown in the drawings are wire bonded packages, in which the semiconductor die is mounted on the die support with its active face opposite from the die support. Wires are then bonded to the contact pads of the semiconductor die and to the exposed electrical contacts of the package to provide the internal connections. However, the examples of bonding dies on a die support shown and described are also applicable to other semiconductor device package configurations.

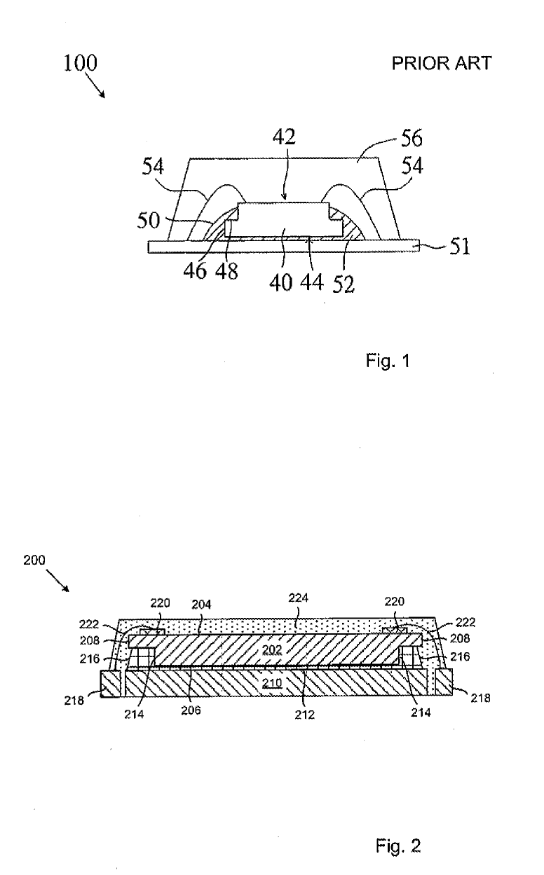

FIG. 1 shows one type of a known packaged semiconductor device 100. The semiconductor device 100 comprises a semiconductor die 40 having first and second opposing faces 42 and 44 and an edge surface 46. The first face 42 of the semiconductor die 40 is an active face and has a plurality of electrical contact elements (not shown). The second face 44 of the semiconductor die 40 is attached to a die support member 51 with a die attach material 52 such as epoxy. The electrical contact elements on the die first face 42 are electrically connected with bond wires 54 to exposed electrical contact elements (not shown) on the die support 51 for connection with external circuits. The die 40 and bond wires 51 are covered with a molding compound 56.

During the bonding of the semiconductor die 40 to the die support 51, the die attach material 52 is viscous. When the second face 44 of the semiconductor die 40 is applied to the die attach material 52, the die attach material 52 is caused to flow out beyond the edge surface 46 of the die 40 to ensure full coverage of the second face 44 and reduce risk of the semiconductor die 40 tilting. Surface tension then causes the die attach material 52 to flow up the edge surface 46, forming a fillet 50. If the fillet 50 has an excessive height that would be indicative of the die attach material 52 flowing over the die edge 46 and onto the active face 42, with the attendant risk of causing defects such as short circuits of the contact pads on the die 40. If the edge surface 46 were planar, so that in cross-section the semiconductor die 40 was rectangular, the die attach material 52 would flow straight up the edge surface 46 of the die. To reduce the risk of overflow of the die attach material 52 onto the active face 42, the known semiconductor device 100 has a step 48 formed in the die edge surface 46. The step 48 is formed in the first face 42 of the semiconductor die 40. The distance that the die attach material 52 can flow over the step 48 before overflowing onto the active face 42 is greater than in the case of a straight edge surface 46. However, the step reduces the width of the active face 42 such that it is less than the width of the opposing face 44, which has the disadvantages of either reducing the number of dies per wafer and/or reducing the number of electrical contact elements that can be located on the active face 42. Further, when the die attach material 52 flows over the step 48 surface tension will still cause the die attach material 52 to flow up towards the active face 42, leaving some risk of the die attach material 52 overflowing onto the active face 42.

FIG. 2 shows an example of a semiconductor device 200 in accordance with an embodiment of the invention. The semiconductor device 200 comprises a semiconductor die 202 having first and second opposed faces 204 and 206 and an edge surface 208. The semiconductor device 200 also comprises a die support member 210, such as a thermally conductive flag of a lead frame, having a bonding surface 212. The semiconductor die 202 has an undercut 214 at the edge 208 that is located below or under the first face 204.

The second face 206 of the semiconductor die 202 is bonded to the bonding surface 212 of the die support member 210 with a die attach material wherein a fillet 216 of the die attach material is formed within the area defined by the undercut 214.

During the process of bonding the second face 206 of the semiconductor die 202 to the bonding surface 212, the undercut 214 contains the die attach material such that the fillet 216 does not extend over the die outer edge 208 and onto the die first face 204. Even if the size of the fillet 216 is excessive, the die attach material will tend to flow outwards, attracted by surface tension with the bonding surface 212, which is generally parallel to the overhang of the undercut 214, rather than flowing up the perpendicular edge surface 208 towards the first face 204, reducing risk of the die attach material overflowing onto the first face 204 and causing a defect.

The first face 204 is an active face of the semiconductor die 202 and has a width greater than the second face 206, which can allow for an increase in the number of dies 202 per wafer and/or an increase in the number of electrical contact elements on the first, active face 204 of the die 202, as compared to the semiconductor device 100.

The semiconductor device 200 includes a set of exposed electrical contact elements 218, which may be formed from part of a lead frame which also provides the die support 210. The active face 204 of the semiconductor die 202 has a plurality of electrical contact elements 220 that are electrically connected with the exposed electrical contact elements 218 such as with bond wires 222, which may be done using known wire bonding processes and equipment. A molding compound 224 covers the first face 204, fillet 216 and bond wires 222.

It will be appreciated that a semiconductor device such as the device 200 may include more than one semiconductor die 202 each of whose edge surfaces 208 includes an undercut 214.

The vertical dimensions in the drawings have been exaggerated relative to the horizontal dimensions for the sake of clarity. By way of example, in one example of a semiconductor die 202, the thickness of the die 202 was reduced to 125 μm by back-grinding the wafer before singulating the dies. The undercut 214 was 50 μm wide and 75 μm high.

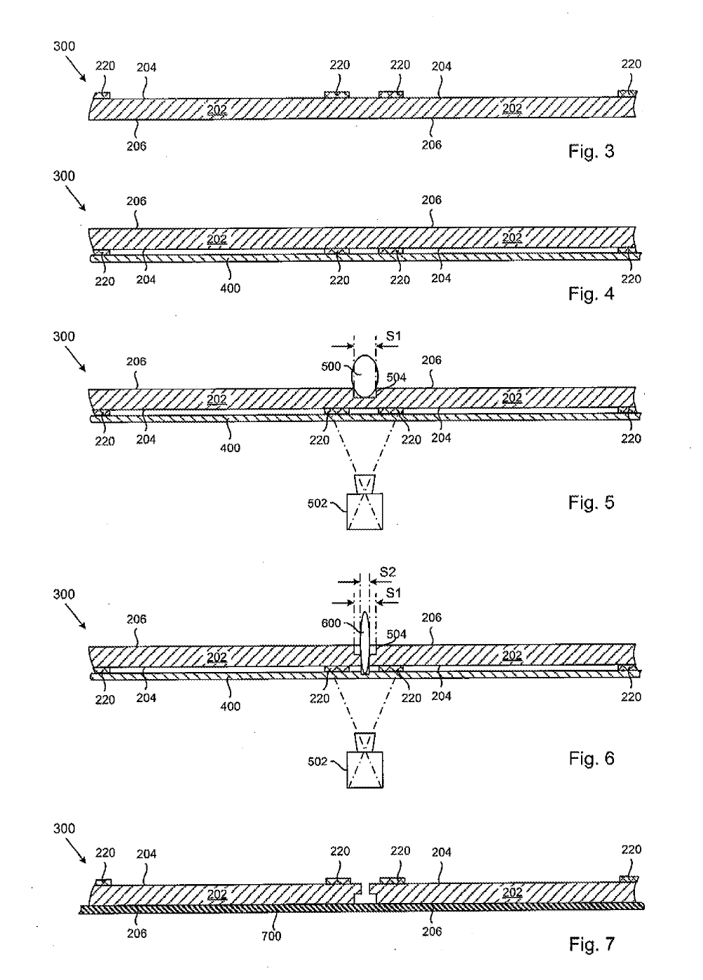

FIGS. 3 to 7 illustrate an example of a method in accordance with an embodiment of the invention of making a semiconductor device such as the device 200. The method starts by providing a wafer 300 in which semiconductor circuits are formed. FIG. 3 is a sectional view of part of the wafer 300, the part shown including material for parts of two adjacent semiconductor dies 202. The method illustrated in FIGS. 3 to 7 comprises providing a semiconductor die 202 having first and second opposed faces 204 and 206 and an edge surface 208. The edge surface 208 of the die has an undercut 214 formed below or under the first face 204. The purpose of the undercut 214 is as previously discussed, to prevent the flow of die attach material onto the first, active face 204 of the die 202 so that the die attach material does not interfere with the electrical connections and electrical contact elements on the first, active face of the die 202.

Referring again to FIG. 3, the top face of the wafer 300 as shown in FIG. 3 forms the first face 204 of the semiconductor dies 202. The bottom face or back side of the wafer 300 as shown in FIG. 3 after back-grinding forms the second face 206 of the semiconductor dies 202. The first face 204 includes a plurality of electrical contact elements 220. The top face of the wafer 300 as shown in FIG. 3 also presents alignment marks (not shown) for guiding singulation and other sawing operations.

As shown in FIG. 4, the wafer 300 is then turned over and mounted with the first faces 204 of the semiconductor dies 202 on a backing 400 such as an adhesive support film.

As shown in FIG. 5, the wafer 300 on the backing 400 is installed in a sawing machine. The sawing machine is represented in the drawing by a first saw blade 500 and a camera 502. The backing and any chuck table interposed between the wafer 300 and the camera 502 are transparent to the camera 502 and the guidance system of the sawing machine. The first saw blade 500 is represented symbolically by an oval but it will be appreciated that the rotating saw blade 500 will in fact be round, with any suitable cross-section. The first saw blade 500 is used to make a first cut in the back side of the wafer 300 to form a groove 504 part way through the thickness of the wafer 300 in the second faces 206 of the semiconductor dies 202. The groove 504 is shown as having a rectangular cross-section but it will be appreciated that the groove 504 may have any suitable cross-section, which will typically be defined by the cross-section of the rotating saw blade 500.

The first saw blade 500 is displaced along a set of parallel saw streets and an orthogonal set of parallel saw streets between adjacent semiconductor dies 202 to form the grooves 504. The displacement of the first saw blade 500 is guided by the alignment marks on the first face 204 of the wafer 300 sensed by the camera 502. A width S1 of the grooves 504 is defined by the width of the first saw blade 500. Each groove 504 will form the undercuts 214 of adjacent semiconductor dies 202. The width S1 of the groove 504 is greater than the widths of the two adjacent undercuts 214, to allow for subsequent singulation of the semiconductor dies 202.

As shown in FIG. 6, in this example of an embodiment of the invention, the semiconductor dies 202 are then singulated. The first saw blade 500 is replaced with a second saw blade 600 and the second saw blade 600 is used to make a second cut along the same set of parallel saw streets and orthogonal set of parallel saw streets between adjacent semiconductor dies 202, again guided by the alignment marks on the top face of the wafer 300 sensed by the camera 502. The width S2 of the second saw blade 600 is less than the width S1 of the first saw blade 500. The second saw blade 600 cuts wholly through the remaining thickness of the wafer 300 in the grooves 504 from the same side as the second faces 206 of the semiconductor dies 202 so as to singulate the semiconductor dies 202.

As shown in FIG. 7, a support material 700 such as an adhesive support film is applied to the second faces 206 of the semiconductor dies 202 after singulation and the backing 400 on the first faces 204 is removed. The semiconductor dies 202 on the support material 700 are then inverted or flipped over and then picked individually from support material 700 with a pick-and-place tool, as is known in the art. Each semiconductor die 202 is then attached to the bonding surface 212 of the die support member 210 with the die attach adhesive and a fillet 216 is formed in the undercut 214.

In this example, the die attach adhesive is applied to the bonding surface 212 of the die support 210. The second face 206 of the semiconductor die 202 is then applied to the die attach material, which flows into the undercut 214 formed by the groove 504 and the fillet 216 is formed. In an example of another embodiment of the invention, the die attach material is applied to the second face 206 of the semiconductor die 202 and the die 202 then is applied to the bonding surface 212 of the die support 210, and once again a fillet 216 is formed in the undercut 214.

After attaching the semiconductor die 202 to the bonding surface 212 of the die support 210, the electrical contact elements 220 of the dies 202 are electrically connected with corresponding ones of the exposed electrical contact elements 218, such as with a known wire bonding process using commercially available wire bonding equipment. After wire bonding, encapsulation is performed with the die 202, bond wires 222, and the fillet 216 being covered with a molding compound 224.

It is convenient to perform the singulation of the wafer 300 on the same machine as cutting the grooves 504. In this example of the method, two blades of different widths are used simultaneously, cutting in different saw streets, with different saw blade heights. It would be possible alternatively to change the broader saw blade for a narrower saw blade and adjust the saw blade height. However, in another example of another embodiment of the invention, the wafer 300 is mounted on the backing 700 after cutting the grooves 504. The singulation of the wafer 300 is then performed subsequently by sawing, scribing or laser cutting.

In the foregoing specification, the invention has been described with reference to specific examples of embodiments of the invention. It will, however, be evident that various modifications and changes may be made therein without departing from the broader spirit and scope of the invention as set forth in the appended claims. For example, the semiconductor die 202 described herein can be any semiconductor material or combinations of materials, such as gallium arsenide, silicon germanium, silicon-on-insulator (SOI), silicon, monocrystalline silicon, the like, and combinations of the above.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Further, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The specifications and drawings are, accordingly, to be regarded in an illustrative rather than in a restrictive sense.

In the claims, the word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A method of assembling a semiconductor device comprising:
providing a semiconductor die having first and second opposing faces and an edge surface, wherein said edge surface has an undercut under said first face;
providing a die support member having a bonding surface; and
attaching said semiconductor die to said bonding surface with a die attach material, wherein the die attach material flows into said undercut and a fillet is formed in said undercut.

2. The method of claim 1, wherein attaching said semiconductor die to said bonding surface includes applying the die attach material to said bonding surface, and applying said second face of said semiconductor die to said die attach material.

3. The method of claim 1, wherein said first face is an active face of said semiconductor die and has a width greater than said second face.

4. The method of claim 3, wherein said semiconductor device has a plurality of exposed electrical contact elements and said semiconductor die has a plurality of electrical contact elements on said active face, the method further comprising the step of electrically connecting said electrical contact elements of said die with said exposed electrical contact elements.

5. The method of claim 4, wherein electrically connecting said electrical contact elements of said die with said exposed electrical contact elements includes bonding wires to said electrical contact elements.

6. The method of claim 5, further comprising encapsulating said semiconductor die, bond wires and fillet with a molding compound, wherein said first face is embedded in said molding compound.

7. The method of claim 1, wherein providing said semiconductor die includes mounting a wafer of semiconductor material with said first face of said die on a backing material, performing a first sawing operation with a first saw blade having a first width to form said undercut, wherein said first sawing operation includes sawing partially through said wafer, and performing a second sawing operation with a second saw blade having a second width that is less than said first width, wherein said second sawing operation singulates said semiconductor dies.

8. The method of claim 7, wherein singulating said dies includes sawing wholly through said wafer along saw streets with said second saw blade

9. The method of claim 7, wherein said wafer includes alignment marks on said first faces of said dies, said alignment marks for guiding the first saw blade during said first sawing operation.

10. The method of claim 9, further comprising mounting the singulated wafer with said second face of said die on a further support material after said sawing wholly through said wafer along said saw streets.

11. The method of claim 7, further comprising back grinding said wafer to produce said second face of said die.

12. A semiconductor die, comprising:
first and second opposing faces and an edge surface, wherein said edge surface includes an undercut under said first face into a die attach material can flow can flow during bonding of said second face to a bonding surface such that a filler of the die attach material is formed within said undercut.

13. The semiconductor die of claim 12, wherein said first face is an active face having a plurality of electrical contact elements for connection to a corresponding plurality of exposed electrical contact elements of a packaged device.

14. A semiconductor device, comprising:
a semiconductor die having first and second opposing faces and an edge surface, wherein said edge surface includes an undercut under said first face; and
a die support member having a bonding surface, wherein said second face of said semiconductor die is bonded to said bonding surface with a die attach material, and a fillet of said die attach material is formed in said undercut.

15. The semiconductor device of claim 14, wherein said first face is an active face of said semiconductor die and has a width greater than said second face.

16. The semiconductor device of claim 15, further comprising a plurality of exposed electrical contact elements, wherein said active face of said semiconductor die has a corresponding plurality of electrical contact elements electrically connected with said exposed electrical contact elements.

17. The semiconductor device of claim 16, wherein said electrical contact elements of said die are electrically connected with said exposed electrical contact elements with bond wires.

18. The semiconductor device of claim 14, further comprising a molding compound that covers at least said first face of said semiconductor die and said fillet.
